(19) United States
(12) Patent Application Publication
(10) Pub. No.: US 2014/0225062 A1
(43) Pub. Date: Aug. 14, 2014

(54) NITRIDE SEMICONDUCTOR LIGHT EMITTING ELEMENT AND METHOD FOR MANUFACTURING NITRIDE SEMICONDUCTOR LIGHT EMITTING ELEMENT

(71) Applicant: Yufeng Weng, Osaka-shi (JP)

(72) Inventor: Yufeng Weng, Osaka-shi (JP)

(73) Assignee: Sharp Kabushiki Kaisha, Osaka-shi, Osaka (JP)

(21) Appl. No.: 14/350,051

(22) PCT Filed: Jul. 30, 2012
(86) PCT No.: PCT/JP2012/069287

§ 371 Date: Apr. 4, 2014

(30) Foreign Application Priority Data
Oct. 5, 2011 (JP) 2011-220800

(51) Int. Cl. H01L 33/38; H01L 33/06

(52) U.S. Cl. CPC H01L 33/385; H01L 33/06
USPC 257/13; 438/47

(57) ABSTRACT

A nitride semiconductor light emitting element is provided with: a substrate; a nitride semiconductor laminate section on the substrate; a current diffusion layer that is provided on the nitride semiconductor laminate section; a first protection film that is provided on the current diffusion layer; and a first electrode. The nitride semiconductor laminate section has: a first conductivity-type nitride semiconductor layer that is provided on the substrate; an active layer that is provided on the first conductivity-type nitride semiconductor layer; and a second conductivity-type nitride semiconductor layer that is provided on the active layer. The first electrode is electrically connected to the first conductivity-type nitride semiconductor layer. Furthermore, a part of the first electrode is formed above the second conductivity-type nitride semiconductor layer with the first protection film therebetween.

### CROSS-REFERENCE TO RELATED APPLICATIONS

This application is a national stage application under 35 USC 371 of International Application No. PCT/JP2012/069287, filed Jul. 30, 2012, which claims the priority of Japanese Application No. 2011-220800, filed Oct. 5, 2011, the contents of which prior applications are incorporated herein by reference.

### FIELD OF THE INVENTION

The present invention relates to a semiconductor light emitting device that is produced by using a nitride semiconductor material and a method for producing the semiconductor light emitting device, more particularly, to a nitride semiconductor light emitting device and a method for producing the nitride semiconductor light emitting device.

### BACKGROUND OF THE INVENTION

A general nitride semiconductor light emitting device includes an n-type nitride semiconductor layer, a light emitting layer, and a p-type nitride semiconductor layer that are successively laminated on a sapphire substrate. A p-side electrode and an n-side electrode for connecting to an external power supply are connected to these p-type nitride semiconductor layer, and n-type nitride semiconductor layer, respectively.

Generally, sheet resistance of the p-type nitride semiconductor layer is higher than the n-type nitride semiconductor layer; for a purpose of aiding electric current diffusion in the p-type nitride semiconductor layer, a transparent electrode layer composed of for example, ITO (indium tin oxide) is laminated on a substantially entire portion of an upper surface of the p-type nitride semiconductor layer, and the p-side electrode is formed on the transparent electrode layer. In this way, the transparent electrode layer transmits light from the light emitting layer and functions as an electric-current diffusion layer.

Besides, in a case where an insulating substrate such as a sapphire substrate or the like is used for the nitride semiconductor light emitting device, it is impossible to form the n-side electrode on a rear surface of the substrate; accordingly, the n-side electrode is formed on a principal surface that is the same side as the p-side electrode. For example, in semiconductor light emitting devices of patent documents 1-5, the p-side electrode is formed on an upper portion of the p-type semiconductor layer, the p-type semiconductor layer and the light emitting layer on a part region are removed by etching to partially expose the n-type nitride semiconductor layer, and the n-side electrode is formed on the exposed region.

The p-side electrode and the n-side electrode are formed relatively thick by using a metal material, so that light emitted from the light emitting layer cannot pass through the p-side electrode and the n-side electrode. Accordingly, conventionally, because of light absorption by the p-side electrode and the n-side electrode, there is a problem that the nitride semiconductor light emitting device has a large loss in light output efficiency.

Accordingly, in the patent document 4, to suppress the light absorption by the p-side electrode and the n-side electrode, it is proposed to improve the light output efficiency by forming a transparent electroconductive film under the p-side electrode and the n-side electrode. Besides, in the patent document 5, as to a nitride semiconductor light emitting device that is mounted by flip chip attaching, a structure is proposed, in which the n-side electrode secures ohmic contact with the n-type nitride semiconductor layer via a through-hole that penetrates from the p-type nitride semiconductor layer to the n-type nitride semiconductor layer.

### PATENT LITERATURE

PLT1: JP-A-2011-71340

PLT2: JP-A-2011-66461

PLT3: JP-A-1996-250769

PLT4: JP-A-2005-317931

PLT5: JP-A-2011-71339

### SUMMARY OF THE INVENTION

However, to mount, by face up attaching, the nitride semiconductor light emitting device that employs such an electrode arrangement, the p-side electrode and the n-side electrode need a constant mount area to perform wire bonding. Especially, to secure a constant connection area for the n-side electrode, a widely exposed region of the n-type nitride semiconductor layer becomes necessary in accordance with the secured area. Because of this, there is a problem that the chip size becomes large. Besides, in a case where the chip size is not enlarged, the light emitting area of the nitride semiconductor light emitting device becomes all the smaller because the exposed region of the n-type nitride semiconductor layer is enlarged. Because of this, a problem occurs, in which the light output efficiency of the nitride semiconductor light emitting device deteriorates. The patent documents 1-5 take no consideration for such problems.

Besides, as to the light output efficiency, in the patent document 4, a first transparent electrode layer functioning as the electric-current diffusion layer and a second transparent electrode layer for suppressing the light absorption by the p-side electrode and the n-side electrode are formed separately from each other under the p-side electrode and the n-side electrode. Further, work functions of the p-type semiconductor layer and n-type semiconductor layer differ from each other; accordingly, under the p-side electrode and the n-side electrode, pre-process steps different from each other become necessary to secure ohmic contact between the electrode and the transparent electrode layer. Because of this, the number of steps increases to complicate the production processes, and a problem which incurs increase in the production cost is likely to occur.

Besides, in the patent document 5, the n-side electrode can secure ohmic contact with the n-type semiconductor layer via several small through-holes. However, if the semiconductor light emitting device having such a structure is mounted by face up attaching, a step occurs at a center of the n-side electrode, and the attachment of an Au ball is likely to deteriorate when wire bonding is performed. Further, to perform the wire bonding avoiding the step that occurs at the center of the n-side electrode, it is necessary to further increase the electrode area to secure a planar area. In this case, the percentage of light blocked by the electrode increases; accordingly, the light output efficiency further deteriorates.

The present invention has been made in light of the above problems, and it is an object of the present invention to provide a nitride semiconductor light emitting device and a method for producing the nitride semiconductor light emitting device that are able to secure the largest light emitting area and further improve the light output efficiency without enlarging the chip size.

To achieve the above object, a nitride semiconductor light emitting device according to the present invention comprises: a substrate; a nitride semiconductor laminate portion that is laminated on the substrate and includes a first electroconductive-type nitride semiconductor layer disposed on the substrate, an active layer disposed on the first electroconductive-type nitride semiconductor layer, and a second electroconductive-type nitride semiconductor layer disposed on the active layer; an electric-current diffusion layer disposed on the nitride semiconductor laminate portion; a first protection film disposed on the electric-current diffusion layer; and a first electrode electrically connected to the first electroconductive-type semiconductor layer; wherein a part of the first electrode is formed on an upper portion of the second electroconductive-type nitride semiconductor layer via the first protection film.

According to the above structure, the part of the first electrode electrically connected to the first electroconductive-type nitride semiconductor layer is formed on the upper portion of the second electroconductive-type nitride semiconductor layer via the first protection film, whereby it is possible to minimize reduction in the light emitting area due to the forming of the first electrode. Accordingly, without enlarging the chip size, it is possible to obtain the nitride semiconductor light emitting device that is able to secure the maximum light emitting area and further improve the light output efficiency.

Further, it is possible to secure the maximum contact area between the electric-current diffusion layer and the second electroconductive-type nitride semiconductor layer; accordingly, it is possible to achieve reduction in driving voltage of the nitride semiconductor light emitting device.

Besides, in the above structure, in plan viewing when seeing from vertically above a principal surface of the nitride semiconductor laminate portion, a groove portion may be formed on at least a region along a part of a periphery of the first electrode to reach the first electroconductive-type nitride semiconductor layer.

Besides, in the above structure, a part of the first electrode may be formed on an upper portion of the electric-current diffusion layer via the first protection film.

Besides, in the above structure, the nitride semiconductor light emitting device further comprises a second electrode disposed on the electric-current diffusion layer, wherein the first electrode includes a first reflective electrode layer disposed between the first electrode and the first electroconductive-type nitride semiconductor laminate portion; the second electrode includes a second reflective electrode layer disposed between the second electrode and the second electroconductive-type nitride semiconductor laminate portion; and the first reflective electrode layer and the second reflective electrode layer may reflect light emitted from the active layer.

Besides, in the above structure, the nitride semiconductor light emitting device further comprises the second electrode disposed on the electric-current diffusion layer, wherein in the plan viewing when seeing from vertically above the principal surface of the nitride semiconductor laminate portion, a part of the first protection film may be formed in a region that substantially overlaps the second electrode.

Besides, in the above structure, the nitride semiconductor light emitting device further comprises a second protection film disposed on at least the first protection film, wherein a refractive index of the second protection film may be lower than a refractive index of the first protection film.

Besides, to achieve the above object, a method for producing a nitride semiconductor light emitting device according to the present invention comprises: a step for laminating, on a substrate, a nitride semiconductor laminate portion that includes a first electroconductive-type nitride semiconductor layer disposed on the substrate, an active layer disposed on the first electroconductive-type nitride semiconductor layer, and a second electroconductive-type nitride semiconductor layer disposed on the active layer; a step for disposing an electric-current diffusion layer on the nitride semiconductor laminate portion; a step for disposing a first protection film on the electric-current diffusion film; and a step for disposing a first electrode electrically connected to the first electroconductive-type nitride semiconductor layer; wherein in the step for disposing the first electrode, a part of the first electrode is formed on an upper portion of the second electroconductive-type nitride semiconductor layer via the first protection film.

According to the above structure, the part of the first electrode electrically connected to the first electroconductive-type nitride semiconductor layer is formed on the upper portion of the second electroconductive-type nitride semiconductor layer via the first protection film, whereby it is possible to minimize the reduction in the light emitting area due to the forming of the first electrode. Accordingly, without enlarging the chip size, it is possible to obtain the method for producing the nitride semiconductor light emitting device that is able to secure the maximum light emitting area and further improve the light output efficiency.

Besides, in the above structure, the step for disposing the first electrode may include: a step for forming a step portion to expose the first electroconductive-type nitride semiconductor layer in plan viewing when seeing from vertically above a principal surface of the nitride semiconductor laminate portion; a step for forming a groove portion on at least a region along a part of a periphery of the first electrode to reach the first electroconductive-type nitride semiconductor layer in the plan viewing when seeing from vertically above the principal surface of the nitride semiconductor laminate portion; and a step for forming the first electrode onto an upper portion of the second electroconductive-type nitride semiconductor layer in at least parts of the step portion and groove portion, and forming the part of the first electrode onto the upper portion of the second electroconductive-type nitride semiconductor layer via the first protection film.

According to the present invention, it is possible to easily obtain a nitride semiconductor light emitting device and a method for producing the nitride semiconductor light emitting device that are able to secure the maximum light emitting area and further improve the light output efficiency without enlarging the chip size.

### BRIEF DESCRIPTION OF THE DRAWINGS

FIG. 1A is a sectional structural view of a nitride semiconductor light emitting device according to an embodiment.

FIG. 1B is a top view of a nitride semiconductor light emitting device according to an embodiment.

FIG. 2 is an enlarged sectional view around a p-side electrode and an n-side electrode.

FIG. 3A is a sectional structural view for describing a process for forming a nitride semiconductor laminate portion.

FIG. 3B is a sectional structural view for describing a process for laminating an electric-current block layer.

FIG. 3C is a sectional structural view for describing a process for forming an electric-current block layer by etching.

FIG. 3D is a sectional structural view for describing a process for forming an electric-current diffusion layer.

FIG. 3E is a sectional structural view for describing a process for forming a step portion and a groove portion.

FIG. 3F is a sectional structural view for describing a process for forming a first protection film.

FIG. 3G is a sectional structural view for describing a process for forming an n-side electrode and a p-side electrode.

FIG. 3H is a sectional structural view for describing a process for forming a second protection film.

FIG. 4 is a sectional structural view of a nitride semiconductor light emitting device according to a modification of an embodiment.

FIG. 5 is a top structural view of a nitride semiconductor light emitting device according to another modification of an embodiment.

FIG. 6 is a top structural view of a nitride semiconductor light emitting device according to another modification of an embodiment.

FIG. 7 is a top structural view of a nitride semiconductor light emitting device according to another modification of an embodiment.

### DETAILED DESCRIPTION OF THE INVENTION

Hereinafter, embodiments of the present invention are described with reference to the drawings; however, a specific structure is not limited to the embodiments, but modifications within a scope not-departing from the spirit of the present invention are covered by the present invention.

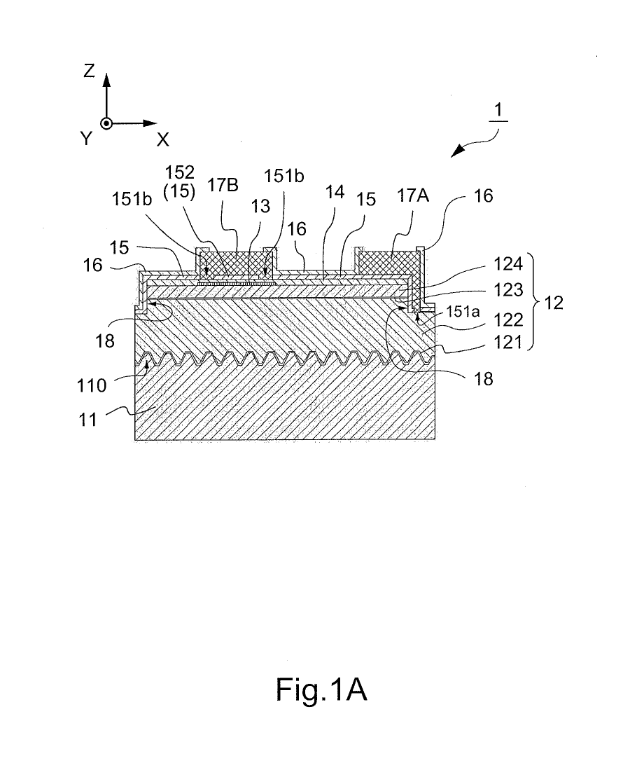

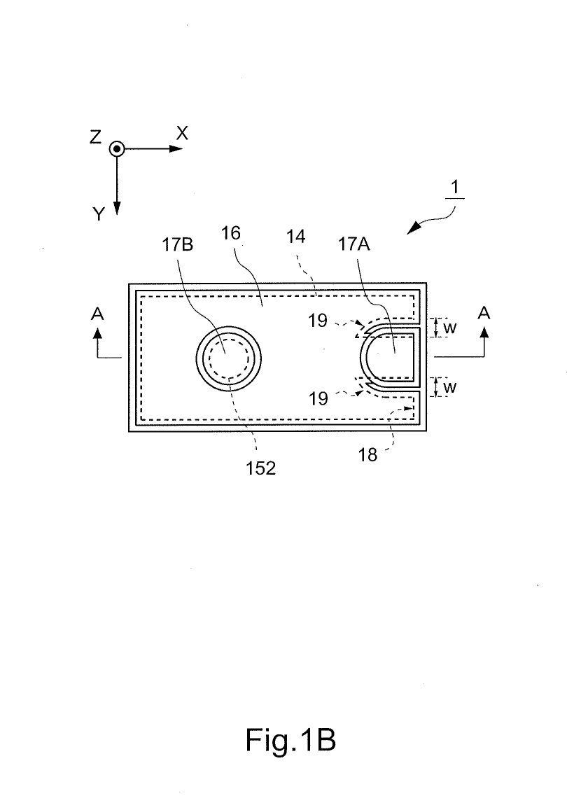

FIG. 1A is a sectional structural view of a nitride semiconductor light emitting device according to an embodiment. Besides, FIG. 1B is a top view of the nitride semiconductor light emitting device according to the present embodiment. FIG. 1A shows a vertical sectional view along an A-A line of FIG. 1B. First, with reference to FIG. 1A and FIG. 1B, a structure of the nitride semiconductor light emitting device 1 according to the present embodiment is described.

As shown in FIG. 1A, the nitride semiconductor light emitting device 1 includes: a substrate 11; a nitride semiconductor laminate portion 12; an electric-current block layer 13; an electric-current diffusion layer 14; a first protection film 15; a second protection film 16; an n-side electrode 17A (first electrode); and a p-side electrode 17B (second electrode). Besides, the nitride semiconductor laminate portion 12 is composed of a plurality of epitaxial layers that are formed by using InₓAl_{y}Ga_{1-x-y}N (0≦x<1, 0≦y<1). Specifically, the nitride semiconductor laminate portion 12 is structured to include: a buffer layer 121; an n-type nitride semiconductor layer 122; an active layer 123; and a p-type nitride semiconductor layer 124.

In the meantime, in the present embodiment, the n-type nitride semiconductor layer 122 is an example of a first electroconductive-type nitride semiconductor layer of the present invention, while the p-type nitride semiconductor layer 124 is an example of a second electroconductive-type nitride semiconductor layer of the present invention.

The substrate 11 is a sapphire substrate, for example, and has principal surfaces in a (0001) direction. One principal surface of the substrate 11 is provided with a plurality of substrate convex portions 110. This substrate convex portion 110 has a substantially truncated cone shape or a substantially conical shape. The substrate convex portion 110 has a height of 0.6 μm in a normal direction of the principal surface of the substrate 11. Besides, in plan viewing when seeing from the normal direction of the principal surface of the substrate 11, a plan shape of the substrate convex portion 110 on the principal surface of the substrate 11 is, for example, a circular shape having a diameter of 1 μm. Besides, in the plan viewing when seeing from the normal direction of the principal surface of the substrate 11, the substrate convex portions 110 are regularly disposed such that centers of the plan shapes of the respective substrate convex portions 110 on the principal surface of the substrate 11 are situated respectively at vertexes of a virtual equilateral triangle and are arranged in three-edge directions of this virtual equilateral triangle. Besides, a pitch between the substrate convex portions 110 is 2 μm, for example. As described above, because the plurality of substrate convex portions 110 are formed on the principal surface of the substrate 11, it is possible to improve an internal quantum effect and light output efficiency of the nitride semiconductor light emitting device 1 when the nitride semiconductor laminate portion 12 is laminated on the principal surface.

Specifically, it is possible to laminate the nitride semiconductor laminate portion 12 having a low dislocation density onto the principal surface of the substrate 11 by means of a LEPS (Lateral Epitaxy on the Patterned Substrate) method. According to the LEPS method, for example, crystal growth is performed preferentially in a substantially normal direction of a side surface of the substrate convex portion 110; accordingly, in the crystal growth process, dislocation in a grown film is bent by a faceted surface. As a result of this, in the crystal growth process, propagation of the dislocation in the substantially normal direction (e.g., a Z direction of FIG. 1A) of the principal surface of the substrate 11 is suppressed; accordingly, the dislocation density in the grown film decreases. Because of this, it is possible to improve the internal quantum effect of the nitride semiconductor light emitting device 1.

Besides, the refractive index of the nitride semiconductor laminate portion 12 is large; accordingly, total light reflection easily occurs inside the conventional nitride semiconductor light emitting device. On the other hand, as in the nitride semiconductor light emitting device 1 according to the present embodiment, by forming the plurality of substrate convex portions 110 onto the principal surface of the substrate 11, it is possible to scatter light and suppress the total light reflection. Besides, by reducing the pitch between the substrate convex portions 110, a light diffraction effect also is expectable. Accordingly, when mounting the nitride semiconductor light emitting device 1 by face down attaching such as flip chip attaching or the like, it is possible to improve the light output efficiency.

On the principal surface of the substrate 11, the nitride semiconductor laminate portion 12 is laminated by the LEPS method, for example. Specifically, the n-type nitride semiconductor layer 122 is laminated via the buffer layer 121 that is formed by using AIN. This n-type nitride semiconductor layer 122 is structured to include a ground layer (not shown) that is formed by using GaN and a contact layer (not shown) that is formed by using n-type GaN with Si doped. The ground layer has, for example, a thickness of 9 μm, while the contact layer has, for example, a thickness of 2 μm. Besides, the contact layer has, for example, a carrier concentration of about 6×10¹⁸ cm⁻³. Besides, the active layer 123 is laminated on the n-type nitride semiconductor layer 122. This active layer 123 has a multi-quantum well structure that is obtained by repeatedly laminating alternately well layers and barrier layers. In the present embodiment, the well layer is formed by using n-type In_{0.15}Ga_{0.85}N, and its thickness is 3.5 nm, for example. Besides, the barrier layer is formed by using Si-doped GaN, and its thickness is 6 nm, for example. The p-type nitride semiconductor layer 124 is laminated on the active layer 123.

Besides, on a part region of an upper surface of the p-type nitride semiconductor layer 124, the electric-current block layer 13 is formed by using a transparent dielectric material such as, for example, SiO₂ or the like (see FIG. 1A). In the meantime, hereinafter, the part region of the upper surface of the p-type nitride semiconductor layer 124 on which the electric-current block layer 13 is formed is called a first region.

In plan viewing when seeing from vertically above the principal surface of the nitride semiconductor laminate portion 12 (e.g., from a Z direction of FIG. 1A), this first region substantially overlaps the p-side electrode 17B. Because of this, an electric current from the p-type electrode 17B does not flow into the first region situated right under the p-side electrode 17B but flows into a region other than the first region that contributes to the light emission. Accordingly, it is possible to improve the light output efficiency of the nitride semiconductor light emitting device 1.

Besides, the electric-current block layer 13 is formed by using a material that has a refractive index lower than the p-type nitride semiconductor layer 124; accordingly, light, which is emitted from the active layer 123 and travels toward the p-side electrode 17B, is easily totally reflected by an interface between the p-type nitride semiconductor layer 124 and the electric-current block layer 13 before entering the p-side electrode 17B. For example, when the light, which is emitted from the active layer 123 and travels toward the p-side electrode 17B, enters the electric-current block layer 13 from the p-type nitride semiconductor layer 124, in a case where an incident angle of this light is larger than a critical angle as a condition for the total reflection at the interface between the p-type nitride semiconductor layer 124 and the electric-current block layer 13, this light is totally reflected by the interface between the p-type nitride semiconductor layer 124 and the electric-current block layer 13. Accordingly, it is possible to suppress the light emitted from the active layer 123 being absorbed by the p-side electrode 17B.

Besides, the electric-current diffusion layer 14 is laminated on the electric-current block layer 13 and the p-type nitride semiconductor layer 124. This electric-current diffusion layer 14 is a transparent electroconductive film that is formed by using, for example, ITO (Indium Tin Oxide), and its thickness is 130 nm, for example. In the meantime, it is preferable that the electric-current diffusion layer 14 is in a thickness range of 100 nm to 340 nm. If the thickness of the electric-current diffusion layer 14 is thinner than 100 nm, sheet resistance of the electric-current diffusion layer 14 increases and a driving voltage of the nitride semiconductor light emitting device 1 rises. On the other hand, if the thickness of the electric-current diffusion layer 14 is thicker than 340 nm, it is possible to reduce the driving voltage of the nitride semiconductor light emitting device 1; however, the electric-current diffusion layer 14 absorbs the light emitted from the active layer 123, and the light output from the nitride semiconductor light emitting device 1 declines.

Besides, a refractive index (e.g., n₁₄=1.9) of the electric-current diffusion layer 14 is smaller than a refractive index (e.g., n₁₂₄=2.55) of the p-type nitride semiconductor layer 124. Because of this, the light, which is emitted from the active layer 123, is easily totally reflected by an interface between the p-type nitride semiconductor layer 124 and the electric-current diffusion layer 14 before entering the n-side electrode 17A and the p-side electrode 17B. For example, when the light, which is emitted from the active layer 123 and travels toward the n-side electrode 17A and the p-side electrode 17B, enters the electric-current diffusion layer 14 from the p-type nitride semiconductor layer 124, in a case where an incident angle of this light is larger than a critical angle as a condition for the total reflection at the interface between the p-type nitride semiconductor layer 124 and the electric-current diffusion layer 14, this light is totally reflected by the interface between the p-type nitride semiconductor layer 124 and the electric-current diffusion layer 14. Accordingly, it is possible to further suppress the light absorption at the n-side electrode 17A and the p-side electrode 17B.

Besides, in the plan viewing when seeing from vertically above the principal surface of the nitride semiconductor laminate portion 12 (Z direction), a step portion 18 is formed by etching on peripheral portions of the nitride semiconductor laminate portion 12 and electric-current diffusion portion 14 (see FIG. 1A and FIG. 1B). In the plan viewing when seeing from the Z direction, a width of this step portion 18 is slightly larger than a sum of a film thickness of the first protection film 15 and a film thickness of the second protection film 16 that are described later. Or, the width may be substantially equal to the sum.

Besides, in the plan viewing when seeing from the Z direction, a grove portion 19 is also formed by the etching on a region along a part of a peripheral portion of the n-side electrode 17A (see FIG. 1B). In the plan viewing when seeing from the Z direction, a Y-directional width w of this groove portion 19 is slightly larger than 2 times the sum of the film thickness of the first protection film 15 and the film thickness of the second protection film 16 that are described later. Or, the width may be substantially equal to 2 times the sum, or may be substantially equal to a width of the second protection film 16 formed on the upper surface of the n-side electrode 17A.

Besides, depths of the step portion 18 and groove portion 19 reach the n-type nitride semiconductor layer 122 in the Z direction from an upper surface of the electric-current diffusion layer 14. Besides, in the step portion 18 and the groove portion 19, the n-type nitride semiconductor layer 122 is removed by the etching process or the like at a portion that extends from the upper surface to a predetermined depth.

Besides, the first protection film 15 is formed on the upper surface of the electric-current diffusion layer 14 and inner surfaces of the step portion 18 and groove portion 19. This first protection film 15 is a transparent dielectric film that is formed by using SiO₂ or the like.

Besides, the first protection film 15 is provided with a first opening 151a and a second opening 151b that are formed by the etching. The first opening 151a is an opening for securing ohmic contact between the n-type nitride semiconductor layer 122 and the n-side electrode 17A described later, and is formed on a part of the step portion 18 and on the first protection film 15 on a part region of a bottom surface of the groove portion 19. Besides, the second opening 151b is an opening for securing ohmic contact between the electric-current diffusion layer 14 and the p-side electrode 17B described later, and is formed on a ring-shaped peripheral nearby region (hereinafter, called a ring-shaped region) inside a peripheral portion of a region (hereinafter, called a p-side region) that overlaps the p-side electrode 17B described later in the plan viewing when seeing from the Z direction. In other words, by forming the second opening 151b, in the plan viewing when seeing from the Z direction, a part 152 of the first protection film 15 is formed on an upper portion of a center region, except for the ring-shaped region, of the first region where the electric-current block layer 13 is formed. As describe above, by leaving the part 152 of the first protection film 15 under the p-side electrode 17B, it is possible to raise reflectance of an interface between the first protection film 15 and the p-side electrode 17B to the light emitted from the active layer 123.

Besides, the p-side electrode 17B is formed on an upper portion of the electric-current block layer 13 via the electric-current diffusion layer 14 and the part 152 of the first protection film 15. In other words, in the plan viewing when seeing from the Z direction, the p-side region where the p-side electrode 17B is formed substantially overlaps the first region where the electric-current block layer 13 is formed. Besides, the p-side electrode 17B is in contact with the electric-current diffusion layer 14 on the ring-shaped region.

Besides, on inner sides of the step portion 18 and groove portion 19, the n-side electrode 17A is formed on the n-type nitride semiconductor layer 122 via the first protection film 15. This n-side electrode 17A is electrically connected to the n-type nitride semiconductor layer 122 via the first opening 151a. Besides, a part of this n-side electrode 17A is also formed on an upper portion of the electric-current diffusion layer 14 via the first protection film 15.

According to this, it is possible to minimize reduction in the light emitting area due to the forming of the n-side electrode 17A. Accordingly, without enlarging the chip size (especially, area of the principal surface of the nitride semiconductor light emitting device 1), it is possible to easily obtain the nitride semiconductor light emitting device 1 that is able to secure the maximum light emitting area and further improve the light output efficiency. Further, it is possible to secure the maximum contact area between the electric-current diffusion layer 14 and the p-type nitride semiconductor layer 124; accordingly, it is also possible to achieve reduction in the driving voltage of the nitride semiconductor light emitting device 1.

Besides, the first protection film 15 is formed between the nitride semiconductor laminate portion 12 and the n-side electrode 17A and between the electric-current diffusion layer 14 and the n-side electrode 17A; accordingly, the n-side electrode 17A does not short to the active layer 123, the p-type nitride semiconductor layer 124, and the electric-current diffusion layer 14. Besides, a refractive index (e.g., n₁₅=1.46) of the first protection film 15 is smaller than a refractive index of the n-side electrode 17A; accordingly, it is possible to raise reflectance of the interface between the first protection film 15 and the n-side electrode 17A to the light emitted from the active layer 123.

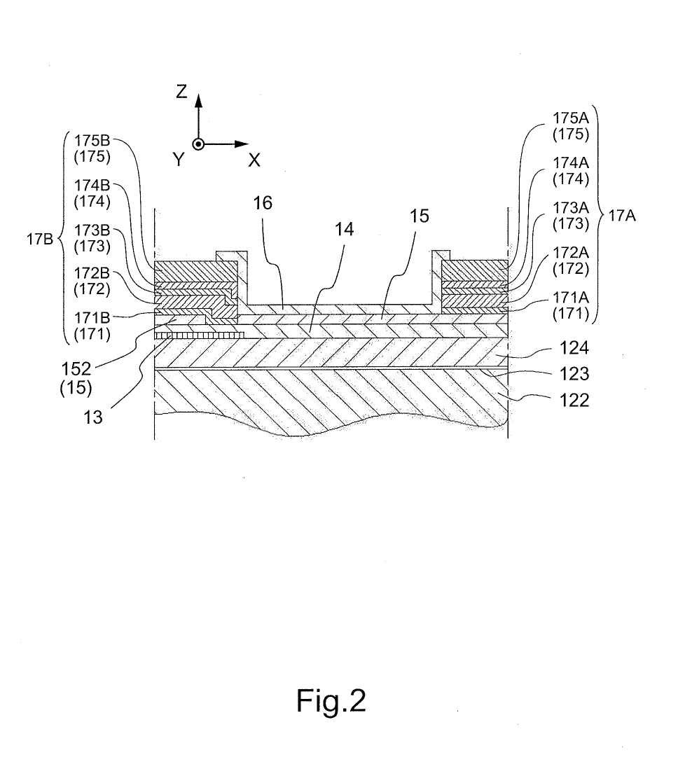

Next, the n-side electrode 17A and the p-side electrode 17B are each structured to include: a first tightly attached layer 171; a reflective electrode layer 172; a second tightly attached layer 173; a barrier layer 174; and an electroconductive layer 175. FIG. 2 is a sectional view showing structures of the n-side electrode and p-side electrode according to the present embodiment. As shown in FIG. 2, the n-side electrode 17A has a multi-layer electrode structure in which a first tightly attached layer 171A, a reflective electrode layer 172A, a second tightly attached layer 173A, a barrier layer 174A, and an electroconductive layer 175A are laminated successively on the nitride semiconductor laminate portion 12. Besides, the p-side electrode 17B has a multi-layer electrode structure in which a first tightly attached layer 171B, a reflective electrode layer 172B, a second tightly attached layer 173B, a barrier layer 174B, and an electroconductive layer 175B are laminated successively on the nitride semiconductor laminate portion 12.

The first tightly attached layer 171 and the second tightly attached layer 173 are formed by using Ni, for example. Besides, the reflective electrode layer 172 is formed by using Al, Ag, Rh and the like, and reflects the light emitted from the active layer 123. Besides, the barrier layer 174 is formed by using Pt, for example. According to this, Pt has a high barrier effect; accordingly it is possible to obtain a high barrier effect of the barrier layer (see FIG. 2). Besides, the electroconductive layer 175 is formed by using a material such as Au or the like that has a high electric conductivity.

Next, the second protection film 16 is formed on at least the first protection film 15. Specifically, in the plan viewing when seeing from vertically above the principal surface of the nitride semiconductor laminate portion 12, the second protection film 16 is formed on the first protection film 15 except for the regions where the n-side electrode 17A and the p-side electrode 17B are formed. Further, the second protection film 16 is also formed on side surfaces of the n-side electrode 17A and p-side electrode 17B and on peripheral nearby regions of upper surfaces of the n-side electrode 17A and p-side electrode 17B. This second protection film 16 is a transparent dielectric film (e.g., 1<n₁₆<1.46) that is formed by using a material which has a refractive index lower than the first protection film 15.

In the meantime, in the present embodiment, the active layer 123 exposed to outside by the etching process or the like is already covered by the first protection film 15; accordingly, the forming of the second protection film 16 is not essential. However, forming the second protection film 16 as in the present embodiment is identical to forming, between outside atmosphere (e.g., air) and the first protection film 15, the second protection film 16 which has a refractive index between the refractive index (e.g., refractive index of the air nₐᵢᵣ=1) of the outside atmosphere and the refractive index (e.g., n₁₅=1.46) of the first protection film 15; accordingly, the light emitted to outside from the active layer 123 becomes unlikely to be reflected between the outside atmosphere and the first protection film 15. In other words, reflection amounts of the light, which is emitted to outside from the active layer 123 and reflected by the interface between the first protection film 15 and the second protection film 16 and by the interface between the outside atmosphere and the second protection film 16, become smaller than a reflection amount at the interface between the first protection film 15 and the outside atmosphere. Accordingly, transmittance of the light, which is emitted to outside from the electric-current diffusion layer 14 via a two-layer structure formed by the two protection films 15, 16 that have each a step-wise refractive index, becomes higher than transmittance of the light that is emitted to outside from the electric-current diffusion layer 14 via the first protection film 15. Accordingly, thanks to the two-layer structure formed by the two protection films 15, 16 that have each the step-wise refractive index, it is possible to further improve the light output efficiency of the nitride semiconductor light emitting device 1.

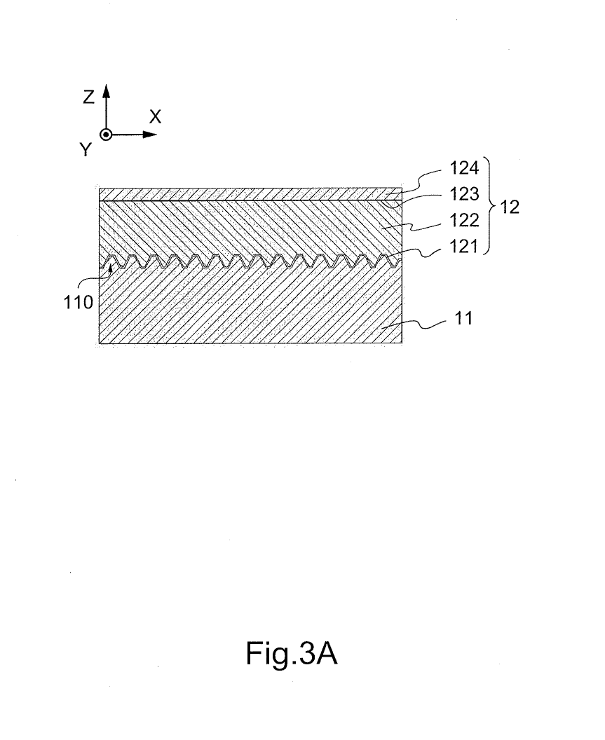

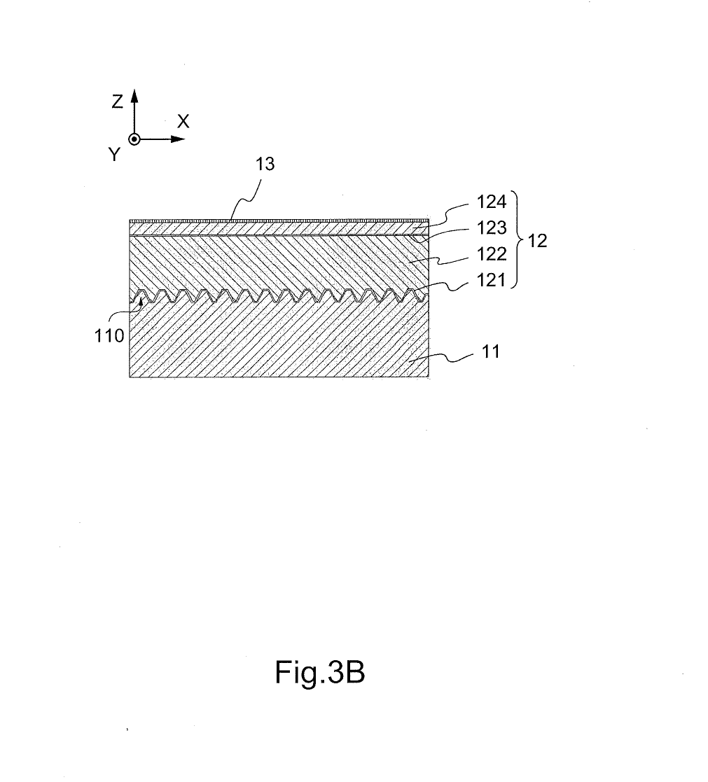

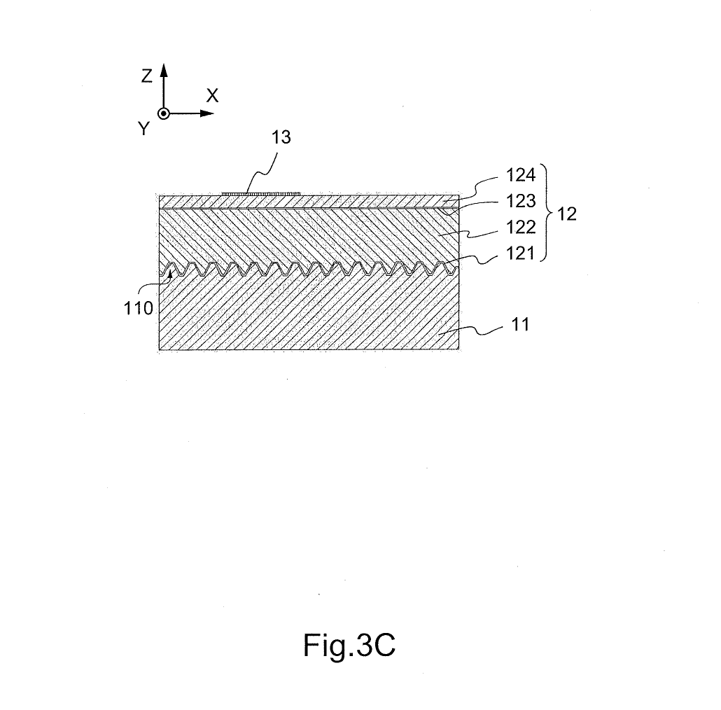

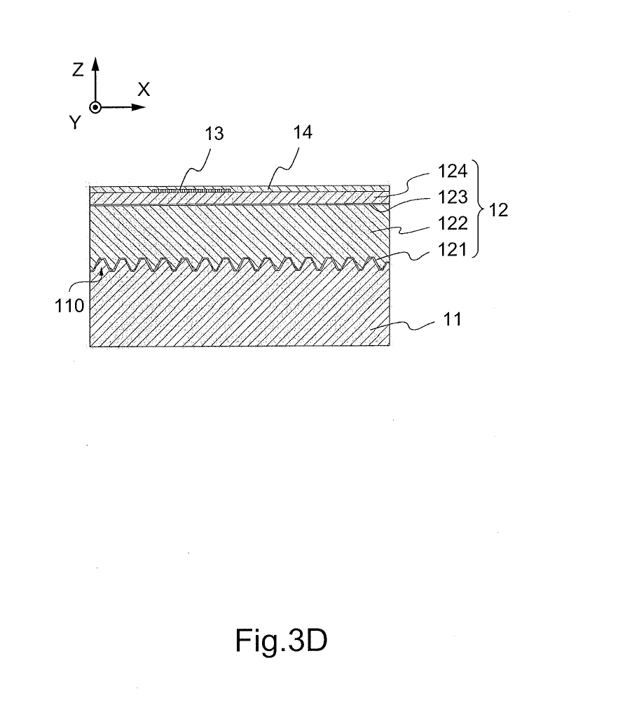

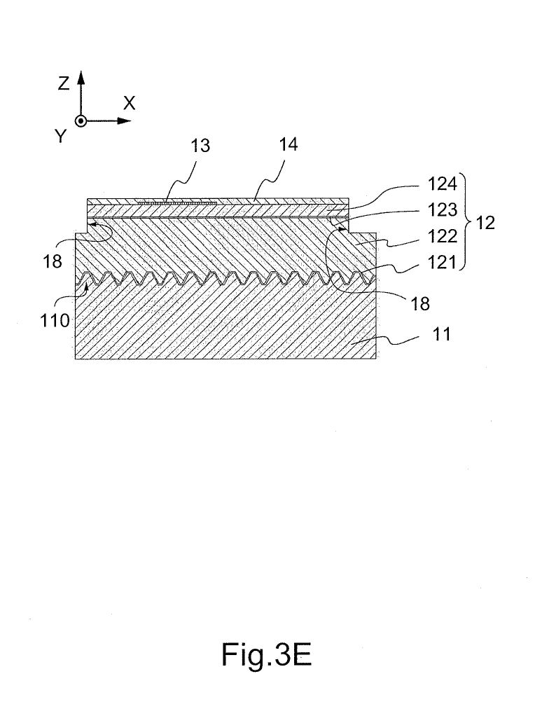

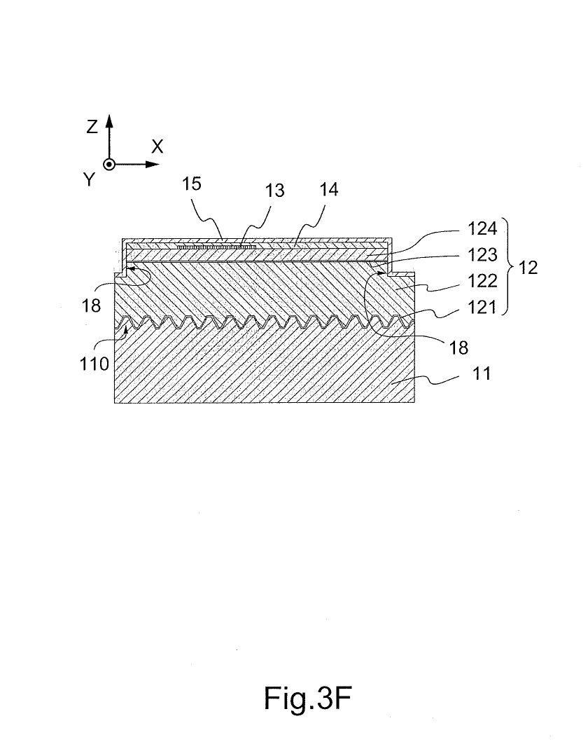

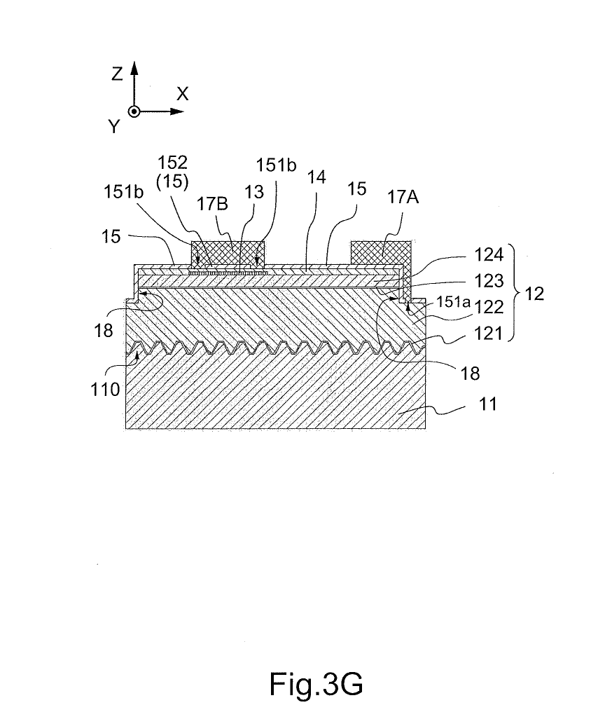

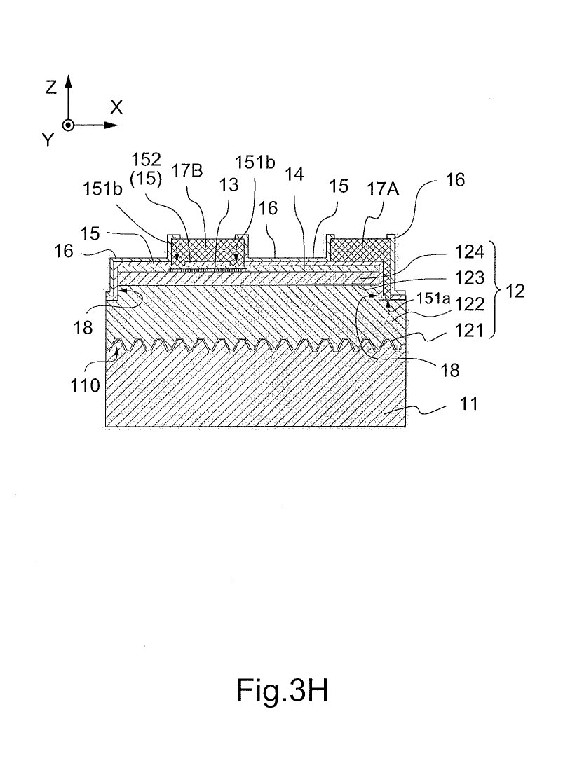

Next, a method for producing the nitride semiconductor light emitting device 1 according to the present embodiment is described. FIG. 3A to FIG. 3H are each a view for describing each production process of the nitride semiconductor light emitting device 1 according to the present embodiment. FIG. 3A is a sectional structural view for describing a process for forming the nitride semiconductor laminate portion. Besides, FIG. 3B is a sectional structural view for describing a process for laminating the electric-current block layer. Besides, FIG. 3C is a sectional structural view for describing a process for forming the electric-current block layer by the etching. Besides, FIG. 3D is a sectional structural view for describing a process for forming the electric-current diffusion layer. Besides, FIG. 3E is a sectional structural view for describing a process for forming the step portion and the groove portion. Besides, FIG. 3F is a sectional structural view for describing a process for forming the first protection film. Besides, FIG. 3G is a sectional structural view for describing a process for forming the n-side electrode and the p-side electrode. Besides, FIG. 3H is a sectional structural view for describing a process for forming the second protection film.

First, the substrate 11 having the principal surface in the (0001) direction is prepared. This substrate 11 is composed of n-type GaAs, for example. And, the plurality of convex portions 110 are formed on the principal surface of the substrate 11 by photo lithography and etching. And, a plurality of epitaxial layers, which are composed of AlₓGa_{y}In_{1-x-y}P (0≦x<1, 0≦y<1) or GaAs, are successively laminated, by means of the LEPS method, on the principal surface of the substrate 11 where the plurality of convex portions 110 are formed, whereby the nitride semiconductor laminate portion 12 is formed.

Specifically, as shown in FIG. 3A, the buffer layer 121 composed of AIN is laminated on the principal surface of the substrate 11 by using an organometal crystal growth method, a molecular beam crystal growth method and the like. Thereafter, under condition that a substrate temperature is about 1000° C., as the n-type nitride semiconductor layer 122, a ground layer (not shown) composed of GaAs and a contact layer (not shown) composed of n-type GaN with Si doped are successively laminated. The ground layer has a thickness of, for example, 9 μm, while the contact layer has a thickness of, for example, 2 μm. Besides, the contact layer has a carrier concentration of, for example, about 6×10¹⁸ cm⁻³. And, under condition that the substrate temperature is about 890° C., on the n-type nitride semiconductor layer 122, a well layer composed of In_{0.15}Ga_{0.85}N and a barrier layer composed of GaN with Si doped are repeatedly laminated alternately 6 times, whereby the active layer 123 is laminated. The p-type nitride semiconductor layer 124 is formed on the active layer 123.

Next, as shown in FIG. 3B, the electric-current block layer 13 is laminated on the p-type nitride semiconductor layer 124. For this electric-current block layer 13, a transparent dielectric material such as SiO₂ or the like which has a relatively low refractive index is used.

After the electric-current block layer 13 is laminated, as shown in FIG. 3C, the electric-current block layer 13 formed on a region other than a predetermined region (i.e., the first region) of the p-type nitride semiconductor layer 124 is removed by the etching by using the photo lithography method.

And, as shown in FIG. 3D, the electric-current diffusion layer 14 composed of, for example, ITO (Indium Tin Oxide) is laminated by sputtering on the electric-current block layer 13 and the p-type nitride semiconductor layer 124. The electric-current diffusion layer 14 has a thickness of 130 nm, for example. In the meantime, the electric-current diffusion layer 14 may be in a thickness range of 100 to 340 nm. Besides, here, the electric-current diffusion layer 14 has a measured sheet resistance of about 200Ω/□.

After the electric-current diffusion layer 14 is formed as a film, a first anneal process is performed for 10 minutes in an mixed gas atmosphere of 2% oxygen and 98% nitrogen under condition that the substrate temperature is 600° C. After the first anneal process is performed, a transmission factor of the electric-current diffusion layer 14 is measured; as a result of this, the transmission factor to light having a wavelength of 450 nm is raised to 94% or more.

After the first anneal process is completed, the electric-current diffusion layer 14 is temporarily exposed to the atmosphere. Thereafter, the device is returned again into an oven, and a second anneal process is performed for 5 minutes in a vacuum atmosphere under condition that the substrate temperature is 500° C. After the second anneal process is performed, the sheet resistance of the electric-current diffusion layer 14 is measured; as a result of this, the sheet resistance decreases to 11Ω/□. As described above, by performing this second anneal process, it is possible to decrease the sheet resistance of the ITO transparent electroconductive film formed as the electric-current diffusion layer 14.

After the second anneal process, as shown in FIG. 3E, part regions of the nitride semiconductor laminate portion 12 and electric-current diffusion layer 14 are partially removed by the etching by using the photo lithography method or the like. Specifically, in the plan viewing when seeing from vertically above the principal surface of the nitride semiconductor laminate layer 12 (Z direction), a peripheral nearby region, which is along all the peripheral portions of: a part of the n-type nitride semiconductor laminate layer 122; active layer 123; P-type nitride semiconductor layer 124; and electric-current diffusion layer 14, is removed by the etching to form the step portion 18. Further, in the plan viewing when seeing from the Z direction, also a region, which is along a part of a peripheral portion of the region where the n-side electrode 17A is formed, is removed by the etching to form the groove portion 19 (see FIG. 1B). Besides, this etching process is performed such that the etching depth reaches a predetermined depth from the upper surface of the n-type nitride semiconductor layer 122. Because of this, when seeing from vertically above the upper surface of the electric-current diffusion layer 14 (Z direction), the n-type nitride semiconductor layer 122 is exposed in the step portion 18 and the groove portion 19.

After the step portion 18 and the groove portion 19 are formed by the etching, as shown in FIG. 3F, the first protection film 15 is formed on the electric-current diffusion layer 14 and the inner surfaces of the step portion 18 and groove portion 19 by plasma CVD (Chemical Vapor Deposition). Besides, for the first protection film 15, a transparent dielectric material such as SiO₂ or the like is used.

After the first protection film 15 is formed, as shown in FIG. 3G, by using an electron beam deposition method and a lift off method, in at least parts of the step portion 18 and groove portion 19, the n-side electrode 17A is formed on an upper portion of the n-type nitride semiconductor layer 122, a part of the n-side electrode 17A is formed on an upper portion of the electric-current diffusion layer 14 via the first protection film 15, further, the p-side electrode 17B is formed on the p-side region on the electric-current diffusion layer 14.

Specifically, for example, by using the photo lithography method, a photo resist pattern is formed on the first protection film 15 except for a part region of a region (hereinafter, called a first n-side region) on the n-type nitride semiconductor layer 122 where the n-side electrode 17A is formed via the first protection film 15 in the step portion 18 and the groove portion 19 and for the ring-shaped region on the electric-current diffusion layer 14. In the meantime, the ring-shaped region is a ring-shaped peripheral nearby region on an inner side of a peripheral portion of a region (i.e., p-side region) of the upper surface of the electric-current diffusion layer 14 where the p-side electrode 17B is formed. And, by removing a part of the first n-side region and the first protection film 15 on an upper portion of the ring-shaped region by the etching process, the first opening 151a and the ring-shaped second opening 151b are formed through the first protection film 15.

After the first opening 151a and the ring-shaped second opening 151b are formed, only the photo resist pattern, which is formed on: the part 152 of the first protection film 15 left on the p-side region; an upper portion of the first n-side region; and an upper portion of a region (hereinafter, called a second n-side region) of the first protection film 15 where a part of the n-side electrode 17A is formed, is removed.

And, by means of the electron beam deposition method, the first tightly attached layer 171, the reflective electrode layer 172, the second tightly attached layer 173, the barrier layer 174, and the electroconductive layer 175 are successively laminated on the p-side region, the first n-side region, and the second n-side region. Thereafter, by means of the lift off method, the first tightly attached layer 171, the reflective electrode layer 172, the second tightly attached layer 173, the barrier layer 174, and the electroconductive layer 175, which are formed on the photo resist pattern, are removed together with the photo resist pattern.

As described above, the n-side electrode 17A, which is structured to include: the first tightly attached layer 171A; the reflective electrode layer 172A; the second tightly attached layer 173A; the barrier layer 174A; and the electroconductive layer 175A, is formed on upper portions of the first n-side region and second n-side region. In other words, in the plan viewing when seeing from the Z direction, the n-side electrode 17A electrically connected to the n-type nitride semiconductor layer 122 is formed on the upper portion of the first n-side region (at least parts of the bottom surfaces of the step portion 18 and groove portion 19) of the n-type nitride semiconductor layer 122. Further, a part of the n-side electrode 17A is also formed on the second n-side region on the upper portion of the electric-current diffusion layer 14 via the first protection film 15. Besides, the p-side electrode 17B, which is structured to include: the first tightly attached layer 171B; the reflective electrode layer 172B; the second tightly attached layer 173B; the barrier layer 174B; and the electroconductive layer 175B, is formed on the p-side region of the electric-current diffusion layer 14.

And, after the n-side electrode 17A and the p-side electrode 17B are formed, by means of the plasma CVD, sputtering or the like, the second protection film 16 composed of SiO₂ is formed in an mixed gas atmosphere that contains SiH₄ and oxygen, for example. Specifically, in the plan viewing when seeing from vertically above the principal surface of the nitride semiconductor laminate portion 12, the second protection film 16 is formed on the first protection film 15, the upper surfaces and side surfaces of the n-side electrode 17A and p-side electrode 17B except for the regions where the n-side electrode 17A and the p-side electrode 17B are formed. Besides, here, by adjusting a flow amount of the SiH₄ gas, a flow amount of the oxygen gas and the like, the second protection film 16 is formed such that a refractive index n₁₆ of the second protection film 16 becomes smaller than a refractive index n₁₅ of the first protection film 15 (n₁₆<n₁₅).

After the second protection film 16 is formed, by using the photo lithography method, openings are formed over the upper surfaces of the n-side electrode 17A and p-side electrode 17B. By forming these openings, the second protection film 16 is disposed on a peripheral nearby region along all the peripheral portions of the upper surfaces of the n-side electrode 17A and p-side electrode 17B.

As described above, it is possible to obtain the nitride semiconductor light emitting device 1 according to the present embodiment.

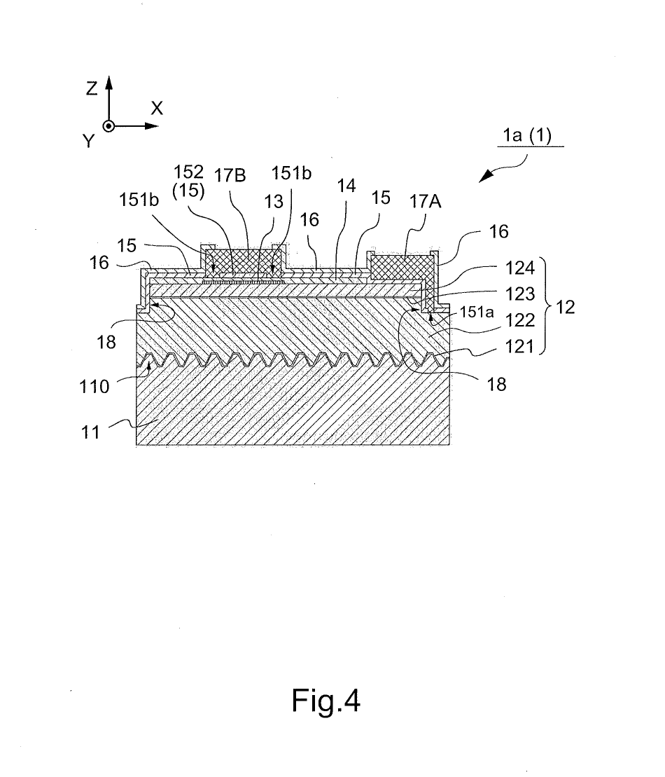

In the meantime, in the above embodiment, the part of the n-side electrode 17A is formed on the upper portion of the electric-current diffusion layer 14 via the first protection film 15; however, as a modification of the present embodiment, the part of the n-side electrode 17A may be formed on an upper portion of the p-type nitride semiconductor layer 124 via the first protection film 15. FIG. 4 is a top view of a nitride semiconductor light emitting device according to the modification of the present embodiment. As in the nitride semiconductor light emitting device 1a shown in FIG. 4, in the plan viewing when seeing from vertically above the principal surface of the nitride semiconductor laminate portion 12, the electric-current diffusion layer 14 may not be formed on an entirety of a region on the p-type nitride semiconductor layer 124 that overlaps the n-side electrode 17A. Further, in the entirety of the region, the part of the n-side electrode 17A may be formed on the upper portion of the p-type nitride semiconductor layer 124 via the first protection film 15.

According to this, the refractive index (e.g., n₁₅=1.46) of the first protection film 15 is smaller than the electric-current diffusion layer 14 (e.g., n₁₄=1.9). Because of this, it is possible to easily totally reflect the light emitted from the active layer 123 at the interface between the p-type nitride semiconductor layer 124 and the first protection film 15. For example, when the light, which is emitted from the active layer 123 and travels toward the n-side electrode 17A, enters the first protection film 15 from the p-type nitride semiconductor layer 124, in a case where the incident angle of this light is larger than a critical angle as a condition for the total reflection at the interface between the p-type nitride semiconductor layer 124 and the first protection film 15, this light is totally reflected by the interface between the p-type nitride semiconductor layer 124 and the first protection film 15. Accordingly, it is possible to more suppress the light absorption at the n-side electrode 17A.

Besides, the electric-current diffusion layer 14 is not formed between the p-type nitride semiconductor layer 124 and the first protection film 15 under the second n-side region where the part of the n-side electrode 17A is formed. Because of this, the electric current from the p-side electrode 17B does not flow into a region right under the second n-side region but flows into a region, other than this region, that contributes to light emission. Accordingly, it is also possible to improve the light output efficiency of the nitride semiconductor light emitting device 1.

Or, in the plan viewing when seeing from the Z direction, the electric-current diffusion layer 14 may not be formed on a part region of the region on the p-type nitride semiconductor layer 124 that overlaps the n-side electrode 17A. For example, in the part region of the region, a part of the n-side electrode may be formed on the upper portion of the p-type nitride semiconductor layer 124 via the first protection film 15, and in a remaining region of the first n-side region, another part of the n-side electrode 17A may be formed on the upper portion of the electric-current diffusion layer 14 via the first protection film 15.

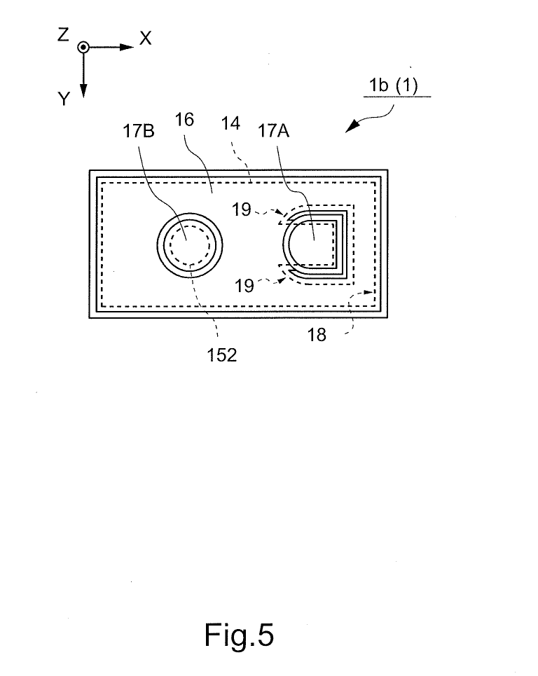

Besides, in the above embodiment, in the plan viewing when seeing from the Z direction, the groove portion 19 is not formed on a part of a region (e.g., left side of the n-side electrode 17A of FIG. 1B) that is a portion of the peripheral nearby region along all the peripheral portions of the n-side electrode 17A and opposite to the p-side electrode 17B; however, the present invention is not limited to this structure. The groove portion 19 may be formed into an arbitrary pattern on at least a part of the peripheral nearby region along all the peripheral portions of the n-side electrode 17A. FIG. 5 to FIG. 7 are each a top view of a nitride semiconductor light emitting device according to another modification of the present embodiment.

For example, as in a nitride semiconductor light emitting device 1b shown in FIG. 5, in the plan viewing when seeing from vertically above the principal surface of the nitride semiconductor laminate portion 12 (Z direction), the n-side electrode 17A and the groove portion 19 may be formed at a position far from the step portion 18.

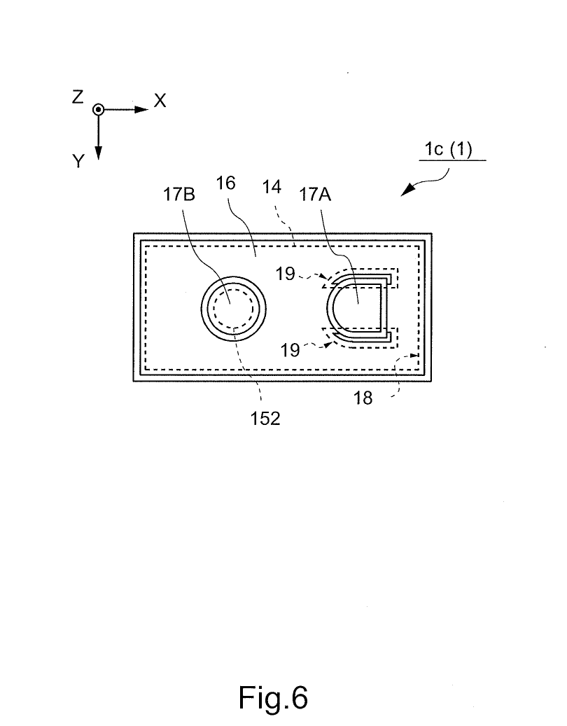

Further, for example, as in a nitride semiconductor light emitting device 1c shown in FIG. 6, the groove portion 19 may not be formed on a part that is a portion of the peripheral nearby region along all the peripheral portions of the n-side electrode 17A and situated at a portion near the p-side electrode 17B and on a part that is a portion of the peripheral nearby region along all the peripheral portions of the n-side electrode 17A and is situated at a portion far from and opposite to the p-side electrode 17B. Further, the electric-current diffusion layer 14 may be continuous in a left-right direction (X direction) of FIG. 6 under the n-side electrode 17A.

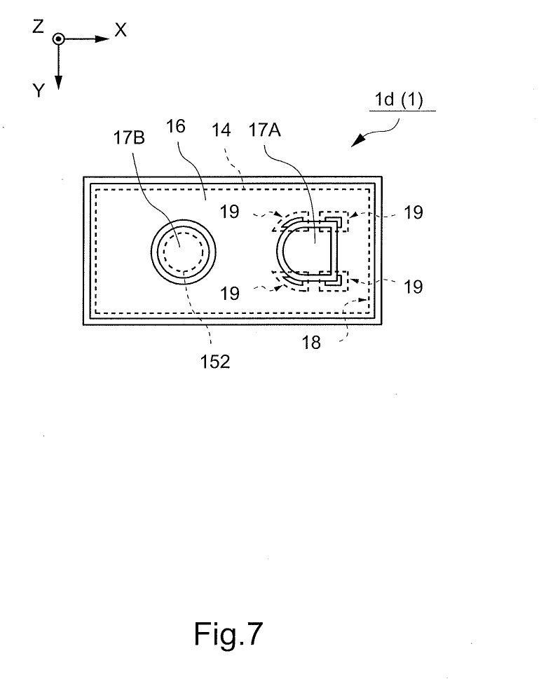

Or, for example, as in a nitride semiconductor light emitting device 1d shown in FIG. 7, the groove portion 19 may be formed at four positions of the peripheral nearby region along all the peripheral portions of the n-side electrode 17A. Further, the electric-current diffusion layer 14 may be continuous in a left-right direction (X direction) and a vertical direction (Y direction) of FIG. 7 under the n-side electrode 17A.

According to these, it is possible to make a conduction state between the n-type nitride semiconductor layer 122 and the n-side electrode 17A more consistent.

Hereinbefore, the present invention is described based on the embodiments. The embodiments are examples, and it is understandable for those skilled in the art that various modified combinations of the components and processes are possible and within the scope of the present invention.

For example, as to the epitaxial layers of the nitride semiconductor laminate portion 12 laminated on the substrate 11, it is possible to suitably combine and modify the thickness, composition and the like to meet a desired characteristic. Besides, in the above embodiments, it is possible to add or delete an epitaxial layer, or change partially the order of laminating the epitaxial layers. Besides, the electroconductive types of some epitaxial layers may be changed.

The present invention is applicable to a light emitting device that is used as a high-brightness light source for a backlight of a liquid crystal display apparatus or for general illumination.

### REFERENCE SIGNS LIST

1 nitride semiconductor light emitting device
11 substrate
110 substrate convex portion
12 nitride semiconductor laminate portion
121 buffer layer
122 n-type nitride semiconductor layer (first electroconductive-type nitride semiconductor layer)
123 active layer
124 p-type nitride semiconductor layer (second electroconductive-type nitride semiconductor layer)
13 electric-current block layer
14 electric-current diffusion layer
15 first protection film
151a first opening
151b second opening
152 part of first protection film
16 second protection film
17A n-side electrode (first electrode)
17B p-side electrode (second electrode)
171 first tightly attached layer
172 reflective electrode layer
173 second tightly attached layer
174 barrier layer
175 electroconductive layer
18 step portion
19 groove portion

1. A nitride semiconductor light emitting device comprising:
a substrate;
a nitride semiconductor laminate portion that is laminated on the substrate and includes a first electroconductive-type nitride semiconductor layer disposed on the substrate, an active layer disposed on the first electroconductive-type nitride semiconductor layer, and a second electroconductive-type nitride semiconductor layer disposed on the active layer;
an electric-current diffusion layer disposed on the nitride semiconductor laminate portion;
a first protection film disposed on the electric-current diffusion layer; and
a first electrode electrically connected to the first electroconductive-type semiconductor layer; wherein
a part of the first electrode is formed on an upper portion of the second electroconductive-type nitride semiconductor layer via the first protection film.

2. The nitride semiconductor light emitting device according to claim 1, wherein
in plan viewing when seeing from vertically above a principal surface of the nitride semiconductor laminate portion, a groove portion is formed on at least a region along a part of a periphery of the first electrode to reach the first electroconductive-type nitride semiconductor layer.

3. The nitride semiconductor light emitting device according to claim 1, wherein
a part of the first electrode is formed on an upper portion of the electric-current diffusion layer via the first protection film.

4. The nitride semiconductor light emitting device according to claim 1, further comprising a second electrode disposed on the electric-current diffusion layer, wherein
the first electrode includes a first reflective electrode layer disposed between the first electrode and the first electroconductive-type nitride semiconductor laminate portion;
the second electrode includes a second reflective electrode layer disposed between the second electrode and the second electroconductive-type nitride semiconductor laminate portion; and
the first reflective electrode layer and the second reflective electrode layer reflect light emitted from the active layer.

5. The nitride semiconductor light emitting device according to claim 1, further comprising the second electrode disposed on the electric-current diffusion layer, wherein
in the plan viewing when seeing from vertically above the principal surface of the nitride semiconductor laminate portion, a part of the first protection film is formed on a region that substantially overlaps the second electrode.

6. The nitride semiconductor light emitting device according to claim 1, further comprising a second protection film disposed on at least the first protection film, wherein
a refractive index of the second protection film is lower than a refractive index of the first protection film.

7. A method for producing a nitride semiconductor light emitting device comprising:
a step for laminating, on a substrate, a nitride semiconductor laminate portion that includes a first electroconductive-type nitride semiconductor layer disposed on the substrate, an active layer disposed on the first electroconductive-type nitride semiconductor layer, and a second electroconductive-type nitride semiconductor layer disposed on the active layer;
a step for disposing an electric-current diffusion layer on the nitride semiconductor laminate portion;
a step for disposing a first protection film on the electric-current diffusion film; and
a step for disposing a first electrode electrically connected to the first electroconductive-type nitride semiconductor layer; wherein
in the step for disposing the first electrode, a part of the first electrode is formed on an upper portion of the second electroconductive-type nitride semiconductor layer via the first protection film.

8. The method for producing a nitride semiconductor light emitting device according to claim 7, wherein
the step for disposing the first electrode includes:
a step for forming a step portion to expose the first electroconductive-type nitride semiconductor layer in plan viewing when seeing from vertically above a principal surface of the nitride semiconductor laminate portion;
a step for forming a groove portion onto at least a region along a part of a periphery of the first electrode to reach the first electroconductive-type nitride semiconductor layer in the plan viewing when seeing from vertically above the principal surface of the nitride semiconductor laminate portion; and
a step for forming the first electrode onto an upper portion of the second electroconductive-type nitride semiconductor layer in at least parts of the step portion and groove portion, and forming the part of the first electrode onto the upper portion of the second electroconductive-type nitride semiconductor layer via the first protection film.
